(19) United States
(12) Patent Application Publication
(10) Pub. No.: US 2025/0324892 A1
(43) Pub. Date: Oct. 16, 2025

(54) DISPLAY PANEL

(71) Applicants: Hefei Visionox Technology Co., Ltd., Hefei (CN); Visionox Technology Inc., Kunshan (CN)

(72) Inventors: Yuting FU, Hefei (CN); Cheng-Yi LIN, Hefei (CN); Wei-Ju HUANG, Hefei (CN); Yi-Yu LAI, Hefei (CN); Cheng-Chu TSENG, Hefei (CN); Jui-Yang TSAI, Hefei (CN); Hsiang-Yin HOU, Hefei (CN); Bowen YANG, Hefei (CN); Chung-Chun LEE, Kunshan (CN)

(73) Assignees: Hefei Visionox Technology Co., Ltd., Hefei (CN); Visionox Technology Inc., Kunshan (CN)

(21) Appl. No.: 19/173,830

(22) Filed: Apr. 9, 2025

(30) Foreign Application Priority Data
Apr. 15, 2024 (CN) 202410451702.5
Aug. 1, 2024 (CN) 202411054495.6

(51) Int. Cl. H10K 59/80; H10K 59/122

(52) U.S. Cl. CPC H10K 59/873; H10K 59/122

(57) ABSTRACT

Embodiments of the disclosure provide a display panel. The display panel includes a plurality of encapsulation units, at least part of each of the encapsulation units includes a first encapsulation portion located in the isolation opening and a second encapsulation portion located on a side of the isolation structure away from the array substrate, a second encapsulation portion of the first light-emitting sub-device includes a first wrapping portion having a first extension length, and a second encapsulation portion of the second light-emitting sub-device includes a second wrapping portion having a second extension length, the first extension length being equal to the second extension length. The disclosure can improve the display effect of the display panel.

### CROSS-REFERENCE TO RELATED APPLICATIONS

The present application claims priorities to Chinese Patent Application No. 202410451702.5 filed on Apr. 15, 2024, and to Chinese Patent Application No. 202411054495.6, entitled “DISPLAY PANEL AND ELECTRONIC DEVICE” and filed on Aug. 1, 2024, the entire contents of which are incorporated herein by reference.

### FIELD

The disclosure relates to the field of display, and particularly to a display panel.

### BACKGROUND ART

Organic light emitting diodes (OLEDs) and flat panel display devices based on technologies such as light emitting diodes (LEDs) have been widely applied to various consumer electronics such as mobile phones, televisions, notebook computers and desktop computers and predominate in display panels thanks to their advantages such as high image quality, energy efficiency, slim design and a wide range of applications.

However, the display panels still have some issues that need to be urgently addressed.

### SUMMARY OF THE INVENTION

In order to overcome the problems mentioned in the above background art, embodiments of the disclosure provide a display panel. The display panel includes:
an array substrate;
an isolation structure, located on one side of the array substrate, the isolation structure enclosing isolation openings;
a plurality of light-emitting devices, located in the isolation openings and comprising a first light-emitting sub-device and a second light-emitting sub-device; and
a first encapsulation layer, located on a side of the light-emitting devices away from the array substrate, the first encapsulation layer comprising a plurality of encapsulation units, each of the encapsulation units correspondingly encapsulating a corresponding one of the light-emitting devices, and at least part of each of the encapsulation units comprising a first encapsulation portion located in a corresponding one of the isolation opening and a second encapsulation portion located on a side of the isolation structure away from the array substrate; wherein the second encapsulation portion correspondingly encapsulating the first light-emitting sub-device comprises a first wrapping portion, in a plurality of cross sections perpendicular to the extension direction of the isolation structure enclosing the first light-emitting sub-device, at least part of the first wrapping portion having a first extension length, and the second encapsulation portion correspondingly encapsulating the second light-emitting sub-device comprises a second wrapping portion, in a plurality of cross sections perpendicular to the extension direction of the isolation structure enclosing the second light-emitting sub-device, at least part of the second wrapping portion having a second extension length, the first extension length being equal to the second extension length.

In some embodiments, the disclosure further provides a display panel, comprising:
an array substrate;
an isolation structure located on one side of the array substrate, the isolation structure enclosing isolation openings;
light-emitting devices located in the isolation openings, the light-emitting devices comprising a plurality of light-emitting sub-devices; and
a first encapsulation layer located on a side of the light-emitting devices away from the array substrate, the first encapsulation layer comprising a plurality of encapsulation units correspondingly encapsulating the light-emitting devices, and at least part of each of the encapsulation units comprising a first encapsulation portion located in the isolation opening and a second encapsulation portion located on a side of the isolation structure away from the array substrate;
wherein the second encapsulation portions on different sides of the same light-emitting sub-device both have equal extension lengths in the direction away from the isolation opening.

Compared with the prior art, the disclosure has the following beneficial effects.

According to the display panel provided by the disclosure, the display effect of the display panel can be improved by setting the length of the wrapping portion located on at least one side of the first light-emitting sub-device in the direction away from the isolation opening to be equal to the length of the wrapping portion located on at least one side of the second light-emitting sub-device in the direction away from the isolation opening.

### BRIEF DESCRIPTION OF THE DRAWINGS

In order to illustrate the embodiments of the disclosure more clearly, the accommodating drawings used in the embodiments will be briefly introduced below. It should be understood that the following drawings only show some embodiments of the disclosure, and therefore should not be considered as a limitation on the scope.

FIG. 1 is a schematic cross-sectional view of a display panel in the related art according to an embodiment of the disclosure;

FIG. 2 is a first schematic cross-sectional view of a display panel according to an embodiment of the disclosure;

FIG. 3 is a schematic partial top view of a display panel according to an embodiment of the disclosure;

FIG. 4 is a second schematic cross-sectional view of a display panel according to an embodiment of the disclosure;

FIG. 5 is a third schematic cross-sectional view of a display panel according to an embodiment of the disclosure;

FIG. 6 is a fourth schematic cross-sectional view of a display panel according to an embodiment of the disclosure;

FIG. 7 is a schematic top view of a first encapsulation unit, a second encapsulation unit and a third encapsulation unit according to an embodiment of the disclosure;

FIG. 8 is a first schematic cross-sectional view of a display panel according to an embodiment of the disclosure that includes a second encapsulation layer and a third encapsulation layer;

FIG. 9 is a second schematic cross-sectional view of a display panel according to an embodiment of the disclosure that includes a second encapsulation layer and a third encapsulation layer; and

FIG. 10 is a schematic cross-sectional view of an isolation structure of a display panel according to an embodiment of the disclosure that includes a three-layer structure.

### DETAILED DESCRIPTION OF EMBODIMENTS

In order to make the embodiments of the disclosure clearer, the embodiments of the disclosure will be described clearly and completely below with reference to the accompanying drawings in the embodiments of the disclosure. Apparently, the embodiments described are some of, rather than all of, the embodiments of the disclosure. Generally, components of the embodiments of the disclosure described and shown in the accompanying drawings herein may be arranged and designed in various configurations.

Thus, the following detailed description of the embodiments of the disclosure provided in the accompanying drawings is not intended to limit the scope of the disclosure as claimed, but is merely representative of the selected embodiments of the disclosure.

It should be noted that similar reference signs and letters refer to similar items in the following drawings. Therefore, once a specific item is defined in one of the drawings, it need not be further defined and explained in subsequent drawings.

In the description of the disclosure, it should be noted that orientations or position relationships indicated by terms such as “center”, “upper”, “lower”, “vertical”, “horizontal”, “inner” and “outer” are on the basis of the orientations or position relationships shown in the drawings or the orientations or position relationships in which a product of the disclosure is customarily placed in use, which is only for ease of describing the disclosure and simplifying the description, rather than indicates or implies that devices or elements referred to must have a specific orientation or be constructed and operated in the specific orientation, and therefore cannot be construed as limiting the disclosure. In addition, the terms “first”, “second”, “third”, etc. are only intended to distinguish between the descriptions, and should not be construed as indicating or implying the relative importance.

It should be noted that, different features in the embodiments of the disclosure can be combined with each other without conflict.

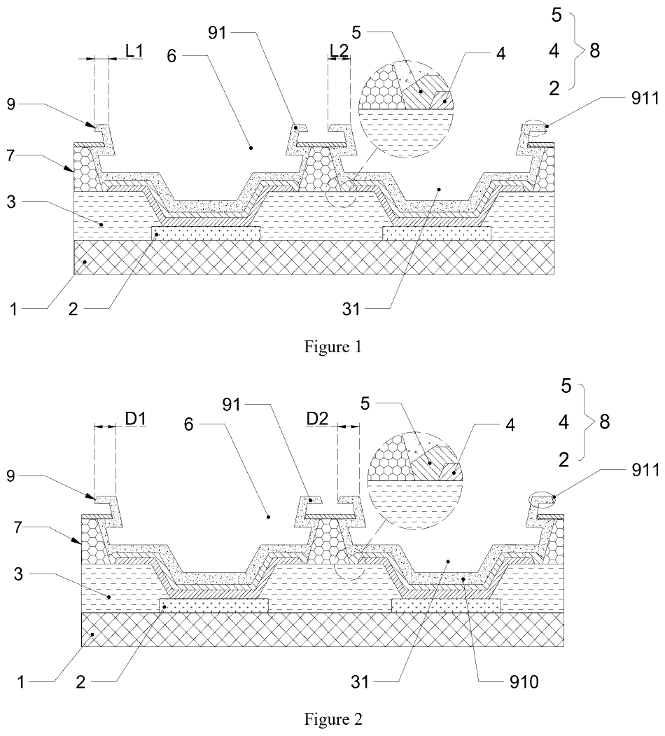

Referring to FIG. 1, a display panel in the related art includes an array substrate 1, an isolation structure 7 located on one side of the array substrate 1, a light-emitting device 8 located in an isolation opening 6 which is enclosed by the isolation structure 7, and a first encapsulation layer 9 located on a side of the light-emitting device 8 away from the array substrate 1. The first encapsulation layer 9 includes a plurality of encapsulation units 91, each of the encapsulation units 91 includes a wrapping portion 911 located on a side of the isolation structure 7 away from the array substrate 1, and the light-emitting device 8 includes a first light-emitting sub-device and a second light-emitting sub-device. According to the order in which the first light-emitting sub-device and the second light-emitting sub-device are manufactured, since the encapsulation unit 91 corresponding to the first light-emitting sub-device is etched again when the second light-emitting sub-device is patterned, in the finally formed display panel, a distance L1 by which the wrapping portion 911 located on at least one side of the first light-emitting sub-device extends in a direction away from the isolation opening 6 is less than a distance L2 by which the wrapping portion 911 located on at least one side of the second light-emitting sub-device extends in the direction away from the isolation opening 6. In this way, the wrapping portions 911 located on the at least one side of the light-emitting sub-devices of different colors in the display panel have different extension distances in the direction away from the isolation openings 6, which ultimately affects the display effect of the display panel.

In view of this, this embodiment provides a solution by which the display effect of the display panel can be improved, and the solution provided in this embodiment will be elaborated below.

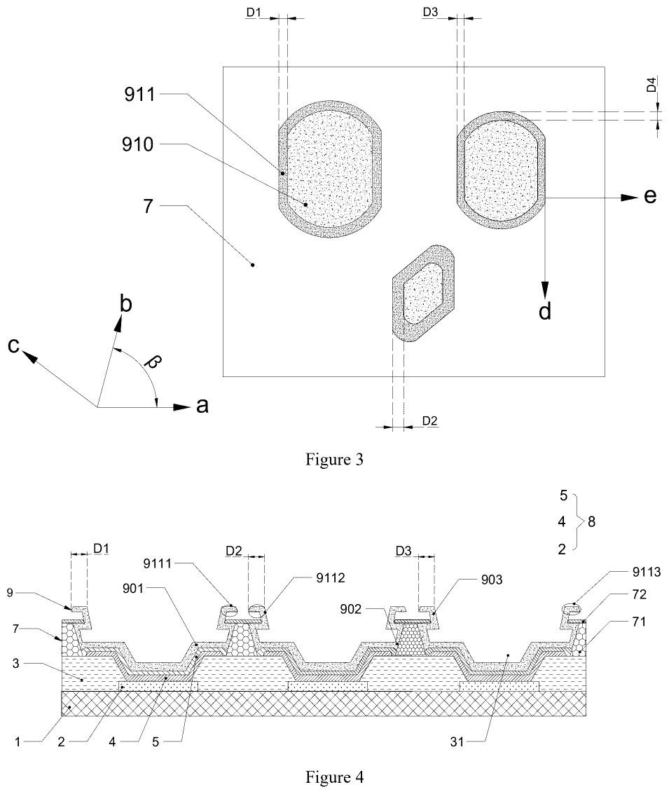

Referring to FIGS. 2 and 3, the embodiment provides a display panel, including an array substrate 1, an isolation structure 7, light-emitting devices 8 and a first encapsulation layer 9.

The array substrate 1 may include a substrate and a plurality of drive units located on one side of the substrate, and each drive unit may include one or more semiconductor switching devices. The semiconductor switching device may be formed collectively by a plurality of membrane layers in the array substrate 1. For example, the semiconductor switching device may be a thin film transistor formed collectively by a plurality of membrane layers.

The isolation structure 7 is located on one side of the array substrate 1, and the isolation structure 7 encloses the isolation openings 6.

The composition, preparation and other contents of the isolation structure 7 are further described in Chinese Patents Applications No. PCT/CN2023/134518, 202310759370.2, 202310740412.8, 202310707209.0, 202311346196.5, 202311499823.9, 202310731471.9, 202311091555.7 for reference.

The light-emitting device 8 is located in the isolation opening 6, and the light-emitting device 8 includes a first light-emitting sub-device and a second light-emitting sub-device; and the first light-emitting sub-device and the second light-emitting sub-device have different light-emitting colors, for example, the light-emitting color of the first light-emitting sub-device may be red, and the light-emitting color of the second light-emitting sub-device may be green.

The first encapsulation layer 9 is located on a side of the light-emitting devices 8 away from the array substrate 1, and the first encapsulation layer 9 includes a plurality of encapsulation units 91, where at least part of each of the encapsulation units 91 extends from a side surface of the isolation structure 7 to a side of the isolation structure 7 away from the array substrate 1, the side surface of the isolation structure 7 being a surface of the isolation structure 7 facing the isolation opening 6.

At least part of each of the encapsulation units 91 includes a first encapsulation portion 910 located in the isolation opening and a second encapsulation portion 911 located on a side of the isolation structure 7 away from the array substrate 1.

The second encapsulation portion 910 of the encapsulation unit 91 correspondingly encapsulating the first light-emitting sub-device includes a first wrapping portion 9111 having a first extension length D1 in a cross section perpendicular to the extension direction of the isolation structure 7 enclosing the first light-emitting sub-device, and the second encapsulation portion 910 of the encapsulation unit 91 correspondingly encapsulating the second light-emitting sub-device includes a second wrapping portion 9112 having a second extension length D2 in a cross section perpendicular to the extension direction of the isolation structure 7 enclosing the second light-emitting sub-device, the first extension length D1 being equal to the second extension length D2.

According to the order in which the first light-emitting sub-device and the second light-emitting sub-device are manufactured, this embodiment ensures that, after the first light-emitting sub-device and the second light-emitting sub-device are manufactured, in the cross sections perpendicular to the extension direction of the isolation structure enclosing the corresponding light-emitting sub-devices, the first extension length D1 of the first wrapping portion 9111 located on at least one side of the first light-emitting sub-device is equal to the second extension length D2 of the second wrapping portion 9112 located on at least one side of the second light-emitting sub-device, that is, orthographic projections on the array substrate 1 of the sides, facing and away from the isolation opening 6, of the parts of the second encapsulation portion 911 corresponding to the first light-emitting sub-device and the second light-emitting sub-device have an equal distance there between.

The cross section corresponding to the first wrapping portion 9111 and perpendicular to the extension direction of the isolation structure 7 enclosing the first light-emitting sub-device, and the cross section corresponding to the first wrapping portion 9111 and perpendicular to the extension direction of the isolation structure 7 enclosing the first light-emitting sub-device may be located in the same preset direction, or in different preset directions. The same preset direction is: a scan signal line direction of a display panel, a data signal line direction of the display panel, an arrangement direction of each light-emitting sub-device, an extension direction of the symmetry axis or center line of the light-emitting device, or a direction with which a scan signal line of the display panel forms an included angle. That is, the direction of the first wrapping portion 9111 on the first sub-device is consistent with the direction of the second wrapping portion 9112 on the second sub-device.

The different preset directions are that: the direction of the first wrapping portion 9111 on the first sub-device is inconsistent with the direction of the second wrapping portion 9112 on the second sub-device.

The length D1 is equal to the length D2 in the extension direction a of the scan signal line of the display panel in FIG. 3. For another example, the length D1 is equal to the length D2 in the extension direction b of the symmetry axis of the light-emitting sub-device in FIG. 3. The direction a may be a direction in which the scan line of the display panel extends in a display area, the direction b and the direction a form an included angle β, and β is in a range of 0°-360°, for example, β may be 60°, 90°, or 120°.

The length D1 being equal to the length D2 herein may not be that the lengths are equal completely, and it may be considered that the length D1 is equal to the length D2 as long as a difference between the length D1 and the length D2 is within a preset error range. For example, the length D1 being greater than the length D2 by 5%-20% may be considered that the length D1 is equal to the length D2. In addition, the extension direction of the isolation structure 7 in the expression “the cross section perpendicular to the extension direction of the isolation structure 7 enclosing the corresponding light-emitting sub-device” refers to an extension direction close to one side surface of the isolation opening 6, and different sections of the isolation structure 7 may have different extension directions. For example, an orthographic projection of the isolation structure 7 on the array substrate 1 has an arc-shaped section, and the extension directions of all the sections of the isolation structure 7 are different; and the isolation structure 7 has a cross section in the direction perpendicular to the extension direction of any one section of the isolation structure 7, the first wrapping portion 9111 or the second wrapping portion 9112 has a line segment having a certain length on a plane where the cross section is located, and the first extension length D1 or the second extension length D2 is the length corresponding to the line segment. As shown in FIG. 3, direction d is the extension direction of the isolation structure 7, and direction e is the extension direction perpendicular to the isolation structure 7. In this way, the encapsulation units 91 have substantially the same effect on the light emission of the first light-emitting sub-device and the second light-emitting sub-device, and the first light-emitting sub-device and the second light-emitting sub-device have better light emission consistency; moreover, by setting the length of the wrapping portions, the encapsulating effect on the light-emitting sub-devices is effectively guaranteed, encapsulation cracks caused by a subsequent process can be avoided, and ultimately the display effect of the display panel can be improved.

On the basis of the above-described design, this embodiment can improve the display effect of the display panel by setting the length D1 of the first wrapping portion 9111 to be equal to the length D2 of the second wrapping portion 9112.

In some embodiments, referring to FIG. 4, the light-emitting device 8 further includes a third light-emitting sub-device; and the second encapsulation portion 911 correspondingly encapsulating the third light-emitting sub-device includes a third wrapping portion 9113, the third wrapping portion 9113 has a third extension length D3 in a cross section perpendicular to the extension direction of the isolation structure 7 enclosing the third light-emitting sub-device, and the third extension length D3 is equal to the first extension length D1 or the second extension length D2. The second encapsulation portion 911 as well as the first wrapping portion 9111, the second wrapping portion 9112 and the third wrapping portion 9113 included thereby have orthographic projections on the array substrate 1, which are within a range of an orthographic projection of the isolation structure 7 on the array substrate 1.

The first light-emitting sub-device, the second light-emitting sub-device and the third light-emitting sub-device have different light-emitting colors. For example, the light-emitting color of the first light-emitting sub-device may be red, the light-emitting color of the second light-emitting sub-device may be green, and the light-emitting color of the third light-emitting sub-device may be blue.

In some embodiments, referring to FIG. 4 again, the second encapsulation portions 911 located on different sides of the same light-emitting sub-device have equal extension lengths in the direction away from the isolation opening 6. That is, the orthographic projection of the second encapsulation portion 911 on the substrate is annular, with uniform width throughout. The length of the second encapsulation portion 911 extending in the direction away from the isolation opening 6 may also be the length of the cross section perpendicular to the extension direction of the isolation structure located below the second encapsulation portion 911. In this way, the same light-emitting sub-device may emit more uniform light in different directions, and the display uniformity of the display panel can be improved.

In an embodiment, the length by which the second encapsulation portion 911 extends in the direction away from the isolation opening 6 is in a range of 2 μm-6 μm, for example, the distance may be 2 μm, 3 μm, 4 μm, 5 μm or 6 μm, etc. By reasonably setting this distance, the display panel can have better encapsulation and display effects.

In some embodiments, referring to FIG. 4 again, the first light-emitting sub-device, the second light-emitting sub-device and the third light-emitting sub-device are arranged adjacent to each other, and the encapsulation unit 91 includes a first encapsulation unit 901 located on a side of the first light-emitting sub-device away from the array substrate 1, a second encapsulation unit 902 located on a side of the second light-emitting sub-device away from the array substrate 1, and a third encapsulation unit 903 located on a side of the third light-emitting sub-device away from the array substrate 1; and the first encapsulation unit 901, the second encapsulation unit 902 and the third encapsulation unit 903 are arranged at intervals, and the second encapsulation portion 9111 of the first encapsulation unit 901 and the second encapsulation portion 9112 of the second encapsulation unit 902 are spaced apart on the side of the isolation structure 7 away from the array substrate 1.

In some embodiments, referring to FIG. 4 again, the second encapsulation portions 911 located on the different sides of the same light-emitting sub-device have equal extension lengths in the direction away from the isolation opening 6. For example, in FIG. 3, the length D4 by which the second encapsulation 911 of the same light-emitting sub-device in the direction b extends in the direction away from the isolation opening 6 is equal to the length D3 by which the second encapsulation 911 in the direction a extends in the direction away from the isolation opening 6, where the direction a may be the direction in which the scan line of the display panel extends in the display area, the direction b and the direction a form the included angle β, and β is in a range of greater than 0° and less than 360°, for example, β may be 60°, 90° or 120°.

In this way, the same light-emitting sub-device may emit more uniform light in different directions, and the display uniformity of the display panel can be improved, and thus the display effect of the display panel can be improved.

In an embodiment, the first light-emitting device and the second light-emitting device are arranged adjacent to each other, and the cross section perpendicular to the extension direction of the isolation structure 7 enclosing the first light-emitting device or the cross section perpendicular to the extension direction of the isolation structure 7 enclosing the second light-emitting device includes: the cross section of the isolation structure 7 passing through the centers of the first light-emitting sub-device and the second light-emitting sub-device which are adjacent to each other, in a direction perpendicular to the plane where the array substrate 1 is located; and the cross section is located on a side surface where the first light-emitting device and the second light-emitting device are close to each other.

The second light-emitting device and the third light-emitting device are arranged adjacent to each other, and the cross section perpendicular to the extension direction of the isolation structure 7 enclosing the second light-emitting device or the cross section perpendicular to the extension direction of the isolation structure 7 enclosing the third light-emitting device includes: the cross section of the isolation structure 7 passing through the centers of the second light-emitting sub-device and the third light-emitting sub-device which are adjacent to each other, in the direction perpendicular to the plane where the array substrate 1 is located.

In an embodiment, in the direction perpendicular to the plane where the array substrate 1 is located, the first wrapping portion 9111 and the second wrapping portion 9112 have equal lengths in the cross section of the isolation structure 7 passing through the centers of the first light-emitting sub-device and the second light-emitting sub-device which are adjacent to each other.

In an embodiment, in the direction perpendicular to the plane where the array substrate 1 is located, the second wrapping portion 9112 and the third wrapping portion 9113 have equal lengths in the cross section of the isolation structure 7 passing through the centers of the second light-emitting sub-device and the third light-emitting sub-device which are adjacent to each other.

In some embodiments, referring to FIG. 4 again, the encapsulation units 91 are arranged at intervals on the side of the isolation structure 7 away from the array substrate 1; there is a gap between the encapsulation unit 91 located on the side of the isolation structure 7 away from the array substrate 1 and the side of the isolation structure 7 away from the array substrate 1; and an orthographic projection of the encapsulation unit 91 on the array substrate 1 covers an orthographic projection of the isolation opening 6 on the array substrate 1, and covers part of an orthographic projection of the isolation structure 7 on the array substrate 1.

In the process of patterning the light-emitting devices 8, the first encapsulation layer 9 is disconnected at the isolation structure 7 to form the encapsulation units 91, and the encapsulation units 91 can encapsulate the corresponding light-emitting devices 8 completely separately, and the display characteristics of the display panel can be improved.

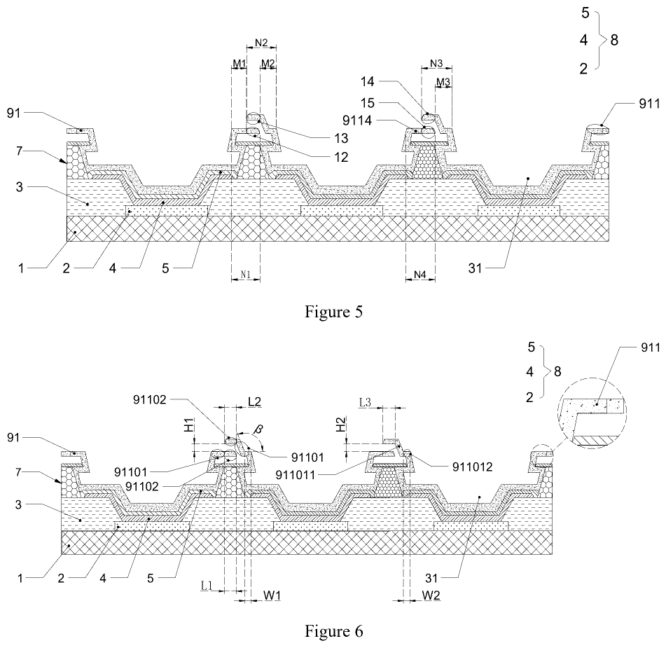

In some embodiments, referring to FIGS. 5 and 6, the second encapsulation portion 911 of the first encapsulation unit 901 and the second encapsulation portion 911 of the second encapsulation unit 902 are partially stacked on the side of the isolation structure 7 away from the array substrate 1.

Each of the second encapsulation portion 911 of the first encapsulation unit 901 and the second encapsulation portion 911 of the second encapsulation unit 902 includes a first extension portion 91101 and a second extension portion 91102 sequentially arranged in a direction away from the isolation opening 6, and an orthographic projection of the second extension portion 91102 of the first encapsulation unit 901 on the array substrate 1 at least partially at least partially overlaps with an orthographic projection of the second extension portion 91102 of the second encapsulation unit 902 on the array substrate 1.

The second extension portion 91102 of the first encapsulation unit 901 and the second extension portion 91102 of the second encapsulation unit 902 are stacked on the isolation structure 7 on the side where the first light-emitting device and the second light-emitting device are close to each other.

In some embodiments, referring to FIGS. 5 and 6, a second encapsulation portion 911 of the third encapsulation unit 903 and the second encapsulation portion 911 of the second encapsulation unit 902 are partially stacked on the side of the isolation structure 7 away from the array substrate. The second encapsulation portion 911 of the third encapsulation unit 903 further includes a first extension portion 91101 and a second extension portion 91102 sequentially arranged in the direction away from the isolation opening 6, an orthographic projection of the second extension portion 91102 of the second encapsulation unit 902 on the array substrate 1 at least partially at least partially overlaps with an orthographic projection of the second extension portion 91102 of the third encapsulation unit 903 on the array substrate 1, the second extension portion 91102 of the third encapsulation unit 903 and the second extension portion 91102 of the second encapsulation unit 902 are stacked on the isolation structure 7 on the side where the third light-emitting device and the second light-emitting device are close to each other, and the second extension portion 91102 of the third encapsulation unit 903 is partially located on a side of the second extension portion 91102 of the second encapsulation unit 902 away from the array substrate 1.

By configuring the second extension portion 91102 of the first light-emitting sub-device to at least partially coincide with the second extension portion 91102 of the second light-emitting sub-device and configuring the second extension portion 91102 of the third light-emitting sub-device to at least partially coincide with the second extension portion 91102 of the second light-emitting sub-device, the encapsulating effect on the first light-emitting sub-device, the second light-emitting sub-device and the third light-emitting sub-device can be improved, and the second extension portion 91102 away from one side of the array substrate 1 can also provide protection to the second extension portion 91102 close to one side of the array substrate 1, and the second extension portion 91102 close to one side of the array substrate 1 is less liable to breakage.

In an embodiment, in the direction perpendicular to the array substrate 1, the thickness of the second light-emitting sub-device is greater than the thickness of the first light-emitting sub-device, and the second extension portion 91102 of the second encapsulation unit 902 is partially located on a side of the second extension portion 91102 of the first encapsulation unit 901 away from the array substrate 1.

In some embodiments, the first wrapping portion 9111 of the first encapsulation unit 901 and the second wrapping portion 9112 of the second encapsulation unit 902 are partially stacked on the side of the isolation structure 7 away from the array substrate 1. That is, the first wrapping portion 9111 and the second wrapping portion 9112 are located at the second encapsulation portion 911 in a stacked arrangement.

In an embodiment, each of the first wrapping portion 9111 and the second wrapping portion 9112 includes a first extension portion 91101 and a second extension portion 91102 sequentially arranged in the direction away from the isolation opening, and an orthographic projection of the second extension portion 91102 of the first wrapping portion 9111 on the array substrate 1 at least partially at least partially overlaps with an orthographic projection of the second extension portion 91102 of the second wrapping portion 9112 on the array substrate.

In an embodiment, the first wrapping portion 9111 has a first extension length N1 in the cross section perpendicular to the extension direction of the isolation structure enclosing the first light-emitting sub-device, and the second wrapping portion 9112 has a second extension length N2 in the cross section perpendicular to the extension direction of the isolation structure 7 enclosing the second light-emitting sub-device, the first extension length N1 being equal to the second extension length N2.

In an embodiment, the second extension portion 91102 of the first wrapping portion 9111 has a first extension sub-length L1 in the cross section perpendicular to the extension direction of the isolation structure enclosing the first light-emitting sub-device, and the second extension portion of the second wrapping portion 9112 has a second extension sub-length L2 in the cross section perpendicular to the extension direction of the isolation structure 7 enclosing the second light-emitting sub-device, the first extension sub-length L1 being equal to the second extension sub-length L2.

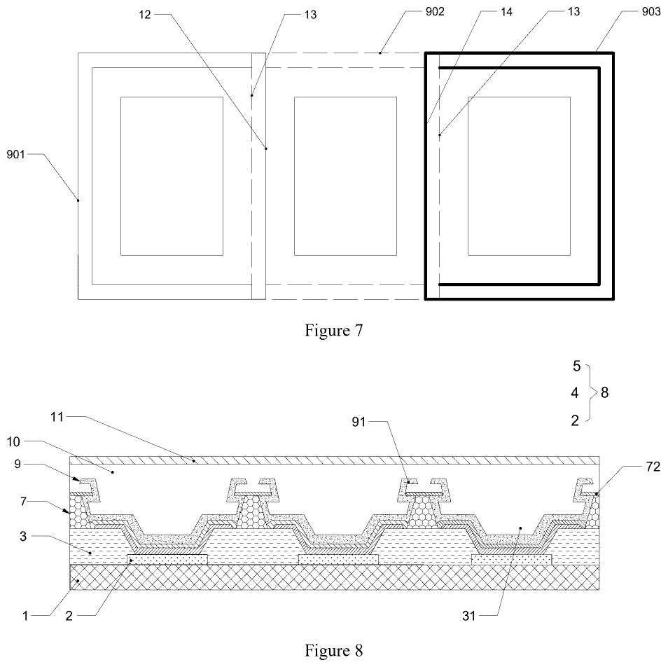

In an embodiment, referring to FIGS. 5-7, the second extension portion 91102 of the first encapsulation unit 901 includes a first extension section 12 close to one side of the second light-emitting sub-device, the second extension portion 91102 of the second encapsulation unit 902 includes a second extension section 13 close to one side of the first light-emitting sub-device, and an orthographic projection of the first extension section 12 on the array substrate 1 at least partially overlaps with an orthographic projection of the second extension section 13 on the array substrate 1.

In an embodiment, in the direction perpendicular to the plane where the array substrate 1 is located, both the first extension section 12 and the second extension section 13 cover the cross section of the isolation structure passing through the centers of the first light-emitting sub-device and the second light-emitting sub-device which are adjacent to each other.

In an embodiment, the second encapsulation portion 911 of the second encapsulation unit 902 further includes a fourth wrapping portion 9114 located on a different side from the second wrapping portion 9112, and a third wrapping portion 91113 of the third encapsulation unit 903 and the fourth wrapping portion 9114 of the second encapsulation unit 902 are partially stacked on the side of the isolation structure 7 away from the array substrate 1.

In an embodiment, the third wrapping portion 9113 includes a first extension portion 91101 and a second extension portion 91102 sequentially arranged in the direction away from the isolation opening, and the orthographic projection of the second extension portion 91102 of the second wrapping portion 9112 on the array substrate 1 at least partially at least partially overlaps with an orthographic projection of the second extension portion 91102 of the third wrapping portion 9113 on the array substrate.

In an embodiment, the fourth wrapping portion 9114 has a fourth extension length N4 in the cross section perpendicular to the extension direction of the isolation structure 7 enclosing the second light-emitting sub-device, and the third wrapping portion 91113 has an equal third extension length N3 in the cross section perpendicular to the extension direction of the isolation structure 7 enclosing the third light-emitting sub-device 903.

In an embodiment, the second extension length N2 may not be equal to the fourth extension length N4. That is, the wrapping portions located on different sides of the second light-emitting sub-device have different extension lengths, and the length of the second encapsulation portion at a non-stacking position of the second encapsulation unit 9112 in the cross section perpendicular to the extension direction of the corresponding isolation structure is not equal to either of the second extension length N2 and the fourth extension length N4.

In an embodiment, referring to FIGS. 5-7, the second extension portion 91102 of the third encapsulation unit 903 includes a third extension section 14 close to one side of the second light-emitting sub-device, the second extension portion 91102 of the second encapsulation unit 902 includes a fourth extension section 15 close to one side of the third light-emitting sub-device, and an orthographic projection of the third extension section 14 on the array substrate 1 at least partially overlaps with an orthographic projection of the fourth extension section 15 on the array substrate 1; and there is a first spacing H1 between the first extension section and the second extension section, and a second spacing H2 between the third extension section 14 and the fourth extension section 15 in the direction perpendicular to the array substrate 1.

In an embodiment, the first spacing H1 is equal to the sum of the thicknesses of a light-emitting functional layer and a second electrode layer of the second light-emitting sub-device, and the second spacing H2 is equal to the sum of the thicknesses of a light-emitting functional layer and a second electrode layer of the third light-emitting sub-device.

In an embodiment, the second extension portion 91102 on the side of the second light-emitting sub-device close to the first light-emitting sub-device is located on the side, away from the array substrate 1, of the second extension portion 91102 on the side of the first light-emitting sub-device close to the second light-emitting sub-device. In this way, the second extension portion 91102 of the second light-emitting sub-device can provide protection to the second extension portion 91102 of the first light-emitting sub-device, and the second extension portion 91102 of the first light-emitting sub-device is less liable to breakage in a subsequent process.

In an embodiment, the extension length L1 of the second extension portion 91102 located on at least one side of the first light-emitting sub-device in the direction away from the isolation opening 6 is equal to the extension length L2 of the second extension portion 91102 located on at least one side of the second light-emitting sub-device in the direction away from the isolation opening 6. In this way, the second extension portion 91102 has substantially the same encapsulating effect on the first light-emitting sub-device and the second light-emitting sub-device, and the light emission consistency of the first light-emitting sub-device and the second light-emitting sub-device of the display panel can be improved.

In an embodiment, referring to FIG. 5 again, an orthographic projection, on the array substrate 1, of the second extension portion 91102 located on the side of the third light-emitting sub-device close to the second light-emitting sub-device at least partially at least partially overlaps with an orthographic projection, on the array substrate 1, of the second extension portion 91102 located on the side of the second light-emitting sub-device close to the third light-emitting sub-device, and an orthographic projection, on the array substrate 1, of the second extension portion 91102 located on at least one side of the third light-emitting sub-device, is located within the orthographic projection of the isolation structure 7 on the array substrate 1.

By configuring the second extension portion 91102 of the second light-emitting sub-device to at least partially coincide with the second extension portion 91102 of the third light-emitting sub-device, the encapsulating effect on the third light-emitting sub-device and the second light-emitting sub-device can be improved, and the second extension portion 91102 away from one side of the array substrate 1 can also provide protection to the second extension portion 91102 close to one side of the array substrate 1, and the second extension portion 91102 close to one side of the array substrate 1 is less liable to breakage.

In an embodiment, the second extension portion 91102 on the side of the third light-emitting sub-device close to the second light-emitting sub-device is located on the side, away from the array substrate 1, of the second extension portion 91102 on the side of the second light-emitting sub-device close to the third light-emitting sub-device. In this way, the second extension portion 91102 of the third light-emitting sub-device can provide protection to the second extension portion 91102 of the second light-emitting sub-device, and the second extension portion 91102 of the second light-emitting sub-device is less liable to breakage in a subsequent process.

In an embodiment, the extension length L3 of the second extension portion 91102 located on the at least one side of the third light-emitting sub-device in the direction away from the isolation opening 6 is equal to the extension length L2 of the second extension portion 91102 located on the at least one side of the second light-emitting sub-device in the direction away from the isolation opening 6. In this way, the second extension portion 91102 has substantially the same encapsulating effect on the third light-emitting sub-device and the second light-emitting sub-device, and the light emission consistency of the third light-emitting sub-device and the second light-emitting sub-device of the display panel can be improved.

In an embodiment, the orthographic projection, on the array substrate 1, of the second extension portion 91102 located on the side of the third light-emitting sub-device close to the second light-emitting sub-device at least partially overlaps with the orthographic projection, on the array substrate 1, of the second extension portion 91102 located on the side of the second light-emitting sub-device close to the third light-emitting sub-device.

By configuring the second extension portion 91102 of the second light-emitting sub-device to completely coincide with the second extension portion 91102 of the third light-emitting sub-device, the encapsulating effect of the encapsulation unit 91 on the third light-emitting sub-device and the second light-emitting sub-device can be further improved, and the second extension portion 91102 away from one side of the array substrate 1 can also provide better protection to the second extension portion 91102 close to one side of the array substrate 1.

In an embodiment, part of the first extension portion 91101 located on the side of the second encapsulation unit 902 close to the first light-emitting sub-device includes a horizontal section 911012 and an inclined section 911011 connected to each other, an end of the inclined section 911011 away from the horizontal section 911012 being connected to the second extension portion 91102; and the first extension portion 91101 located on the side of the third encapsulation unit 903 close to the second light-emitting sub-device includes a horizontal section 911012 and an inclined section 911011 connected to each other, an end of the inclined section 911011 away from the horizontal section 911012 being connected to the second extension portion 91102, and specifically, the horizontal section 911012 being integrally formed with the inclined section 911011.

In this way, it is more convenient to configure the second extension portion 91102 on the side of the second light-emitting sub-device close to the first light-emitting sub-device to be located on the side, away from the array substrate 1, of the second extension portion 91102 located on the side of the first light-emitting sub-device close to the second light-emitting sub-device, and it is more convenient to configure the second extension portion 91102 on the side of the third light-emitting sub-device close to the second light-emitting sub-device to be located on the side, away from the array substrate 1, of the second extension portion 91102 on the side of the second light-emitting sub-device close to the third light-emitting sub-device.

In an embodiment, the length N3 of the third wrapping portion 9113, the length N2 of the second wrapping portion 9112, and the length N1 of the wrapping portion 911 of the first encapsulation unit 901 are all the same. That is, the second wrapping portion 9112 and the fourth wrapping portion 9114 on the different sides of the second light-emitting sub-device have the same length. The length M3 of the first extension portion 91101 of the third encapsulation unit 903 extending in the direction away from the isolation opening 6 is the same as the length M2 of the first extension portion 91101 of the second encapsulation unit 902 extending in the direction away from the isolation opening 6, and the length M1 of the first extension portion 91101 of the first encapsulation unit 901 extending in the direction away from the isolation opening 6 is the same as the length M2 of the first extension portion 91101 of the second encapsulation unit 902 extending in the direction away from the isolation opening 6. The “extension length in the direction away from the isolation opening 6” herein refers to the length of a straight line in the cross section perpendicular to the extension direction of the corresponding isolation structure 7.

In some embodiments, referring to FIG. 6 again, the extension length L1, in the direction away from the isolation opening 6, of the second extension portion 91102 located on the at least one side of the first light-emitting sub-device, is greater than or equal to 1.5 μm and less than or equal to 2 μm, for example, the length L1 may be 1.5 μm, 1.6 μm, 1.7 μm, 1.8 μm, 1.9 μm, or 2 μm. The encapsulating effect on the first light-emitting sub-device can be improved by reasonably setting the length L1.

In an embodiment, the extension length W2, in the direction away from the isolation opening 6, of the horizontal section 911012 of the first extension portion 91101 located on the side of the third light-emitting sub-device close to the second light-emitting sub-device, is equal to the extension length W1, in the direction away from the isolation opening 6, of the horizontal section 911012 of the first extension portion 91101 located on the side of the second light-emitting sub-device close to the first light-emitting sub-device.

In this embodiment, the length W2 and the length W1 are equal but are not completely equal, and it can be considered as the length W2 being equal to the length W1 as long as the ratio of an absolute value of a difference between the length W2 and the length W1 to the length W1 is within 10%. In this way, the consistency of the encapsulating effect of the encapsulation unit 91 on the second light-emitting sub-device and the third light-emitting sub-device can be further improved.

Specifically, the extension length W2, in the direction away from the isolation opening 6, of the horizontal section 911012 of the first extension portion 91101 located on the side of the third light-emitting sub-device close to the second light-emitting sub-device is greater than or equal to 1 μm and less than or equal to 1.2 μm, for example, the length W2 may be 1 μm, 1.05 μm, 1.1 μm, 1.15 μm or 1.2 μm, etc. The encapsulating effect on the third light-emitting sub-device can be further improved by reasonably setting the length W2.

In an embodiment, the included angle β between the horizontal section 911012 and the inclined section 911011 of the first extension portion 91101 located on the side of the third light-emitting sub-device close to the second light-emitting sub-device is greater than or equal to 100° and less than or equal to 150°, for example, the included angle β2 may be 100°, 110°, 120°, 130°, 140° or 150°. The encapsulating effect of the encapsulation unit 91 on the third light-emitting sub-device can be improved by reasonably setting the included angle β2.

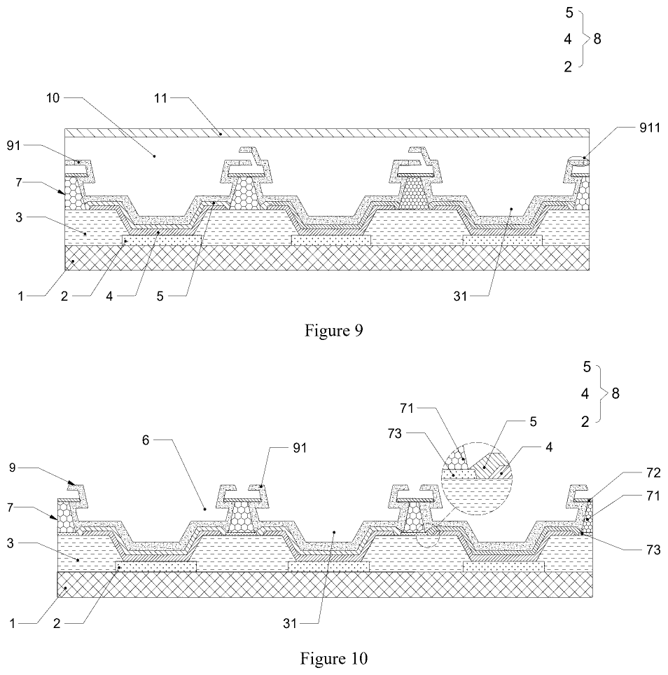

In some embodiments, referring to FIGS. 8 and 9, the display panel further includes a second encapsulation layer 10 located on the side of the first encapsulation layer 9 away from the array substrate 1, and a third encapsulation layer 11 located on the side of the second encapsulation layer 10 away from the array substrate 1; a material of each of the first encapsulation layer 9 and the third encapsulation layer 11 includes an inorganic material; and the material of the second encapsulation layer 10 includes an organic material.

The second encapsulation layer 10 and the third encapsulation layer 11 can play a better encapsulating effect on the light-emitting device 8, and the encapsulation quality of the display panel can be further improved.

In some embodiments, referring to FIG. 6 again, the light-emitting device 8 includes a first electrode layer, a light-emitting functional layer and a second electrode layer which are sequentially stacked in the direction away from the array substrate 1. The display panel further includes a pixel defining layer 3 located on a side of the first electrode layer away from the array substrate 1, and the isolation structure 7 is located on a side of the pixel defining layer 3 away from the array substrate 1; the pixel defining layer 3 includes a pixel opening 31 which exposes at least part of the first electrode 2, and the orthographic projection of the isolation structure 7 on the array substrate 1 is located between orthographic projections of two adjacent pixel openings 31 on the array substrate 1; and the orthographic projection of the pixel opening 31 on the array substrate 1 is located within the orthographic projection of the isolation openings 6 on the array substrate 1.

When the light-emitting functional layer is formed, the light-emitting functional layer is separated by the isolation structure 7 to form a plurality of light-emitting portions 4 arranged at intervals; when the second electrode layer is formed, the second electrode layer is separated by the isolation structure 7 to form a plurality of second electrodes 5 arranged at intervals; and the isolation structure 7 includes a conductive material, the second electrode 5 is electrically connected to the isolation structure 7, and one first electrode 2, one light-emitting portion 4 and one second electrode 5 form one light-emitting device 8. The first electrode 2 is an anode, and the second electrode 5 is a cathode.

In some embodiments, referring to FIG. 4 again, the isolation structure 7 includes a first isolation portion 71 and a second isolation portion 72 sequentially stacked in the direction away from the array substrate 1, and an orthographic projection, on the array substrate 1, of a side of the first isolation portion 71 away from the array substrate 1 is within an orthographic projection of the second isolation portion 72 on the array substrate 1.

Since the second isolation portion 72 is located on the side of the first isolation portion 71 away from the array substrate 11, and the transverse width of the second isolation portion 72 is greater than the transverse width of the first isolation portion 71, the second isolation portion 72 disconnects the light-emitting functional layer and the second electrode layer at the isolation structure 7. In this way, the isolation structure 7 formed by the first isolation portion 71 and the second isolation portion 72 can make it easier to encapsulate each light-emitting device 8 independently.

In some embodiments, referring to FIG. 4 again, the second electrode 5 of the light-emitting device 8 is electrically connected to the first isolation portion 71; and the first isolation portion 71 includes a conductive material, and the second electrode 5 corresponding to the light-emitting device 8 extends to come into contact with a side wall of the first isolation portion 71, to electrically connect the second electrode 5 corresponding to the light-emitting device 8 and the first isolation portion 71.

Referring to FIG. 10, the isolation structure 7 further includes a third isolation portion 73 located on a side of the first isolation portion 71 facing the array substrate 1, and the second electrode 5 of the light-emitting device 8 is electrically connected to the third isolation portion 73.

The third isolation portion 73 includes a conductive material, and the second electrode 5 corresponding to the light-emitting device 8 extends to come into contact with a side wall of the third isolation portion 73, to electrically connect the second electrode 5 corresponding to the light-emitting device 8 and the third isolation portion 73.

Specifically, a material of the third isolation portion 73 includes a molybdenum metal; and/or a material of the first isolation portion 71 includes an aluminum metal; and/or a material of the second isolation portion 72 includes a titanium metal. Thus, when the isolation structure 7 separates the second electrode layer into the second electrodes 5, the second electrodes 5 are more easily electrically connected to the first isolation portion 71 and/or the third isolation portion 73.

In some embodiments, the disclosure further provides another display panel, including an array substrate 1, an isolation structure 7, light-emitting devices 8 and a first encapsulation layer 9.

The isolation structure 7 is located on one side of the array substrate 1, and the isolation structure 7 encloses the isolation openings 6.

The light-emitting device 8 is located in the isolation opening 6, and the light-emitting device 8 includes a plurality of light-emitting sub-devices, for example, the light-emitting device 8 includes a first light-emitting sub-device and a second light-emitting sub-device.

The first encapsulation layer 9 is located on a side of the light-emitting devices 8 away from the array substrate 1, the first encapsulation layer 9 includes a plurality of encapsulation units 91 arranged at intervals, at least part of each of the encapsulation units 91 extends from a side surface of the isolation structure 7 to a side of the isolation structure 7 away from the array substrate 1, and the side surface of the isolation structure 7 is a surface of the isolation structure 7 facing the isolation opening 6.

The encapsulation unit 91 includes a wrapping portion 911 located on the side of the isolation structure 7 away from the array substrate 1, and the wrapping portions 911 on different sides of the same light-emitting sub-device have the same extension length in the direction away from the isolation opening 6.

For example, in FIG. 3, the length D4 by which the wrapping portion 911 of the same light-emitting sub-device in the direction b extends in the direction away from the isolation opening 6 is equal to the length D3 by which the wrapping portion 911 in the direction a extends in the direction away from the isolation opening 6, where the direction a may be the direction in which the scan lines of the display panel extend in the display area, the direction b and the direction a form the included angle β, and β is in the range of greater than 0° and less than 360°, for example, β may be 60°, 90° or 120°.

In this way, the same light-emitting sub-device may emit more uniform light in different directions, and the display uniformity of the display panel can be improved, and thus the display effect of the display panel can be improved.

In some embodiments, referring to FIG. 2 again, the disclosure further provides still another display panel, including an array substrate 1, an isolation structure 7, light-emitting devices 8 and a first encapsulation layer 9.

The isolation structure 7 is located on one side of the array substrate 1, and the isolation structure 7 encloses the isolation openings 6.

The light-emitting device 8 is located in the isolation opening 6, and the light-emitting device 8 includes a plurality of light-emitting sub-devices.

The first encapsulation layer 9 is located on the side of the light-emitting devices 8 away from the array substrate 1, the first encapsulation layer 9 includes a plurality of encapsulation units 91 arranged at intervals, and at least part of each of the encapsulation units 91 includes a first encapsulation portion 910 located in the isolation opening 6 and a second encapsulation portion 911 located on the side of the isolation structure 7 away from the array substrate 1;

where the second encapsulation portions 911 on different sides of the same light-emitting sub-device both have equal extension lengths in the direction away from the isolation opening.

In some embodiments, referring to FIG. 2 again, the disclosure further provides yet another display panel, including an array substrate 1, an isolation structure 7, light-emitting devices 8 and a first encapsulation layer 9.

The isolation structure 7 is located on one side of the array substrate 1, and the isolation structure 7 encloses the isolation openings 6.

The light-emitting device 8 is located in the isolation opening 6, and the light-emitting device 8 includes a plurality of light-emitting sub-devices, for example, the light-emitting device 8 includes a first light-emitting sub-device and a second light-emitting sub-device.

The first encapsulation layer 9 is located on the side of the light-emitting devices 8 away from the array substrate 1, the first encapsulation layer 9 includes a plurality of encapsulation units 91 arranged at intervals, and at least part of each of the encapsulation units 91 includes a first encapsulation portion 910 located in the isolation opening 6 and a second encapsulation portion 911 located on the side of the isolation structure 7 away from the array substrate 1.

The second encapsulation portion 910 of the encapsulation unit 91 correspondingly encapsulating the first light-emitting sub-device includes a first wrapping portion 9111 having a first extension length D1 in a cross section perpendicular to the extension direction of the isolation structure 7 enclosing the first light-emitting sub-device, and the second encapsulation portion 910 of the encapsulation unit 91 correspondingly encapsulating the second light-emitting sub-device includes a second wrapping portion 9112 having a second extension length D2 in a cross section perpendicular to the extension direction of the isolation structure 7 enclosing the second light-emitting sub-device, the first extension length D1 being equal to the second extension length D2.

According to the order in which the first light-emitting sub-device and the second light-emitting sub-device are manufactured, this embodiment ensures that, after the first light-emitting sub-device and the second light-emitting sub-device are manufactured, the length D1 of the first wrapping portion 9111 located on a peripheral side of the first light-emitting sub-device is equal to the length D2 of the second wrapping portion 9112 located on a peripheral side of the second light-emitting sub-device in a preset direction, that is, orthographic projections on the array substrate 1 of the sides, facing and away from the isolation opening 6, of the wrapping portions 911 corresponding to the first light-emitting sub-device and the second light-emitting sub-device have an equal distance there between.

The length D1 being equal to the length D2 herein may not be that the lengths are equal completely, and it may be considered that the length D1 is equal to the length D2 as long as a difference between the length D1 and the length D2 is within a preset error range. For example, the length D1 being greater than the length D2 by 5%-20% may be considered that the length D1 is equal to the length D2. In addition, the isolation opening 6 in the expression “the wrapping portion 911 extends in the direction away from the isolation opening 6” refers to the isolation opening 6 corresponding to the wrapping portion 911. In this way, the encapsulation units 91 have substantially the same effect on the light emission of the first light-emitting sub-device and the second light-emitting sub-device, and the first light-emitting sub-device and the second light-emitting sub-device have better light emission consistency; moreover, by setting the length of the wrapping portions 911, the encapsulating effect on the light-emitting sub-devices is effectively guaranteed, encapsulation cracks caused by a subsequent process can be avoided, and ultimately the display effect of the display panel can be improved.

In some embodiments, referring to FIGS. 5 and 6 again, the disclosure further provides still yet another display panel, including an array substrate 1, an isolation structure 7, light-emitting devices 8 and a first encapsulation layer 9.

The isolation structure 7 is located on one side of the array substrate 1, and the isolation structure 7 encloses the isolation openings 6.

The light-emitting device 8 is located in the isolation opening 6, and the light-emitting device 8 includes a plurality of light-emitting sub-devices, for example, the light-emitting device 8 includes a first light-emitting sub-device and a second light-emitting sub-device.

The first encapsulation layer 9 is located on a side of the light-emitting devices 8 away from the array substrate 1, the first encapsulation layer 9 includes encapsulation units 91, and at least part of each of the encapsulation units 91 extends from a side surface of the isolation structure 7 facing the isolation opening 6 to a side of the isolation structure 7 away from the array substrate 1.

Orthographic projections of adjacent encapsulation units 91 on the array substrate 1 at least partially overlap, the second encapsulation portion 910 of the encapsulation unit 91 correspondingly encapsulating the first light-emitting sub-device includes a first wrapping portion 9111 having a first extension length D1 in a cross section perpendicular to the extension direction of the isolation structure 7 enclosing the first light-emitting sub-device, and the second encapsulation portion 910 of the encapsulation unit 91 correspondingly encapsulating the second light-emitting sub-device includes a second wrapping portion 9112 having a second extension length D2 in a cross section perpendicular to the extension direction of the isolation structure 7 enclosing the second light-emitting sub-device, the first extension length D1 being equal to the second extension length D2.

By configuring the second extension portion 91102 of the first light-emitting sub-device to at least partially coincide with the second extension portion 91102 of the second light-emitting sub-device, the encapsulating effect on the first light-emitting sub-device and the second light-emitting sub-device can be improved, and the second extension portion 91102 away from one side of the array substrate 1 can also provide protection to the second extension portion 91102 close to one side of the array substrate 1, and the second extension portion 91102 close to one side of the array substrate 1 is less liable to breakage.

The display effect of the display panel can be improved by setting the length of the first wrapping portion 9111 located on at least one side of the first light-emitting sub-device to be equal to the length of the second wrapping portion 9112 located on at least one side of the second light-emitting sub-device.

In some embodiments, the disclosure further provides an electronic device, including a display panel in the disclosure, or including a display panel prepared by means of a method for preparing the display panel in the disclosure. The electronic device may include a device having image processing capability, for example, a server, a personal computer, a notebook computer, etc. Since the electronic device includes the display panel in the disclosure, the electronic device has a better display effect.

The embodiments may be combined arbitrarily. For the purpose of simplicity in description, all the possible combinations of the features in the above-described embodiments are not described. However, as long as there is no contradiction among the combinations of these features, they shall all fall within the scope of the description.

The above embodiments merely represent several implementations of the disclosure, giving specifics and details thereof, but should not be understood as limiting the scope of the patent of the disclosure thereby. Therefore, the scope of protection of the patent of the disclosure shall be in accordance with the appended claims.

1. A display panel, comprising:
an array substrate;
an isolation structure, located on one side of the array substrate, the isolation structure enclosing isolation openings;
a plurality of light-emitting devices, located in the isolation openings and comprising a first light-emitting sub-device and a second light-emitting sub-device; and
a first encapsulation layer, located on a side of the light-emitting devices away from the array substrate, the first encapsulation layer comprising a plurality of encapsulation units, each of the encapsulation units correspondingly encapsulating a corresponding one of the light-emitting devices, and at least part of each of the encapsulation units comprising a first encapsulation portion located in a corresponding one of the isolation opening and a second encapsulation portion located on a side of the isolation structure away from the array substrate;
wherein the second encapsulation portion correspondingly encapsulating the first light-emitting sub-device comprises a first wrapping portion, in a plurality of cross sections perpendicular to the extension direction of the isolation structure enclosing the first light-emitting sub-device, at least part of the first wrapping portion having a first extension length, and the second encapsulation portion correspondingly encapsulating the second light-emitting sub-device comprises a second wrapping portion, in a plurality of cross sections perpendicular to the extension direction of the isolation structure enclosing the second light-emitting sub-device, at least part of the second wrapping portion having a second extension length, the first extension length being equal to the second extension length.

2. The display panel according to claim 1, wherein the light-emitting devices further comprise a third light-emitting sub-device, the second encapsulation portion correspondingly encapsulating the third light-emitting sub-device comprises a third wrapping portion, at least part of the third wrapping portion having a third extension length in a plurality of cross sections perpendicular to the extension direction of the isolation structure enclosing the third light-emitting sub-device, the third extension length being equal to the first extension length or the second extension length; and
the first light-emitting sub-device, the second light-emitting sub-device and the third light-emitting sub-device emitting light of different light-emitting colors;
the third extension length is in a range of 2 μm-6 μm.

3. The display panel according to claim 1, wherein an orthographic projection of the first wrapping portion and the second wrapping portion are within a range of an orthographic projection of the isolation structure on the array substrate; and
in a direction perpendicular to a plane where the array substrate is located, the second wrapping portion and the first wrapping portion are located in a cross section of the isolation structure passing through the centers of the first light-emitting sub-device and the second light-emitting sub-device which are adjacent to each other; and
the first extension length and the second extension length in a range of 2 μm-6 μm.

4. The display panel according to claim 1, wherein on a side of the isolation structure away from the array substrate, the second encapsulation portion correspondingly encapsulating the first light-emitting sub-device and the second encapsulation portion correspondingly encapsulating the second light-emitting sub-device are spaced apart from each other;
a gap is disposed between each of the encapsulation units located on a side of the isolation structure away from the array substrate and the side of the isolation structure away from the array substrate.

5. The display panel according to claim 1, wherein the second encapsulation portions on different sides of one of the light-emitting devices both have equal extension lengths in the direction away from the isolation opening; and
wherein in a plurality of cross sections perpendicular to the extension direction of the isolation structure enclosing the first light-emitting sub-device, the first wrapping portion having equal extension lengths; and
wherein in a plurality of cross sections perpendicular to the extension direction of the isolation structure enclosing the second light-emitting sub-device, the second wrapping portion having equal extension lengths.

6. The display panel according to claim 1, wherein the first light-emitting sub-device and the second light-emitting sub-device are arranged adjacent to each other, the encapsulation units comprise a first encapsulation unit located on the side of the first light-emitting sub-device away from the array substrate and a second encapsulation unit located on the side of the second light-emitting sub-device away from the array substrate, and the second encapsulation portion of the first encapsulation unit and the second encapsulation portion of the second encapsulation unit are partially stacked on the side of the isolation structure away from the array substrate; and
each of the second encapsulation portion of the first encapsulation unit and the second encapsulation portion of the second encapsulation unit comprises a first extension portion sequentially arranged in a direction away from a isolation opening of the isolation openings corresponding to the first light-emitting sub-device, each of the second encapsulation portion of the second encapsulation unit comprises a first extension portion and a second extension portion sequentially arranged in a direction away from a isolation opening corresponding to the second light-emitting sub-device; and
an orthographic projection of the second extension portion of the first encapsulation unit on the array substrate at least partially overlaps with an orthographic projection of the second extension portion of the second encapsulation unit on the array substrate.

7. The display panel according to claim 6, wherein the second encapsulation portion of the first encapsulation unit and the second encapsulation portion of the second encapsulation unit, which are partially stacked, are spaced apart on the side of the isolation structure away from the array substrate; and
in a direction perpendicular to the array substrate, the thickness of the second light-emitting sub-device is greater than the thickness of the first light-emitting sub-device, and the second extension portion of the second encapsulation unit is partially located on a side of the second extension portion of the first encapsulation unit away from the array substrate; and
there is a gap between the encapsulation unit located on a side of the isolation structure away from the array substrate and the side of the isolation structure away from the array substrate.

8. The display panel according to claim 7, wherein each of the first wrapping portion and the second wrapping portion comprise a first extension portion and a second extension portion, the second extension portion located on a side of the first extension portion away from the isolation opening, and an orthographic projection of the second extension portion of the first wrapping portion on the array substrate overlaps with an orthographic projection of the second extension portion of the second wrapping portion on the array substrate.

9. The display panel according to claim 8, wherein in a plurality of cross sections perpendicular to the extension direction of the isolation structure enclosing the first light-emitting sub-device, at least part of the second extension portion of the first wrapping portion has a first extension sub-length, and in a plurality of cross sections perpendicular to the extension direction of the isolation structure enclosing the second light-emitting sub-device, at least part of the second extension portion of the second wrapping portion has a second extension sub-length, the first extension sub-length being equal to the second extension sub-length.

10. The display panel according to claim 8, the second extension portion of the first encapsulation unit comprises a first extension section close to one side of the second light-emitting sub-device, the second extension portion of the second encapsulation unit comprises a second extension section close to one side of the first light-emitting sub-device, and an orthographic projection of the first extension section on the array substrate at least partially overlaps with an orthographic projection of the second extension section on the array substrate.

11. The display panel according to claim 8, in a direction perpendicular to the plane where the array substrate is located, both the first extension section and the second extension section cover a cross section of the isolation structure passing through the centers of the first light-emitting sub-device and the second light-emitting sub-device which are adjacent to each other; and
part of the first extension portion located on the side of the second encapsulation unit close to the first light-emitting sub-device comprises a horizontal section and an inclined section connected to each other, an end of the inclined section away from the horizontal section being connected to the second extension portion of the second encapsulation unit;
the first extension portion and the second extension portion are integrally formed; and
the horizontal section and the inclined section are integrally formed.

12. The display panel according to claim 6, wherein the light-emitting devices further comprise a third light-emitting sub-device, the encapsulation units comprise a third encapsulation unit located on a side of the third light-emitting sub-device away from the array substrate, and the second encapsulation portion of the third encapsulation unit and the second encapsulation portion of the second encapsulation unit are partially stacked on the side of the isolation structure away from the array substrate;
an orthographic projection, on the array substrate, of an extension portion located on the side of the third encapsulation unit close to the second light-emitting sub-device at least partially overlaps with an orthographic projection, on the array substrate, of the extension portion located on the side of the second encapsulation unit close to the third light-emitting sub-device.

13. The display panel according to claim 6, wherein the second encapsulation portion of the second encapsulation unit further comprises a fourth wrapping portion located on a different side from the second wrapping portion of the second encapsulation unit, and a third wrapping portion of the third encapsulation unit and the fourth wrapping portion of the second encapsulation unit are partially stacked on the side of the isolation structure away from the array substrate;
in a plurality of cross sections perpendicular to the extension direction of the isolation structure enclosing the second light-emitting sub-device, at least part of the fourth wrapping portion has a fourth extension length, and in a plurality of cross sections perpendicular to the extension direction of the isolation structure enclosing the third light-emitting sub-device, at least part of the third wrapping portion has a third extension length, the fourth extension length being equal to the third extension length;
the fourth extension length is equal to the second extension length; and
the second encapsulation portion of the third encapsulation unit partially stacked is located on the side of the second encapsulation portion of the second encapsulation unit away from the array substrate.

14. The display panel according to claim 12, wherein the third wrapping portion of the third encapsulation unit and the fourth wrapping portion of the second encapsulation unit are partially stacked on the side of the isolation structure away from the array substrate;
in an extension direction perpendicular to the plane where the array substrate is located and in a cross section of the isolation structure passing through central axes of the third light-emitting sub-device and the second light-emitting sub-device which are adjacent to each other, the third wrapping portion and the fourth wrapping portion are stacked on the side of the isolation structure away from the array substrate;
each of the third wrapping portion and the fourth wrapping portion comprises a first extension portion and a second extension portion, the second extension portion located on a side of the first extension portion arranged in the direction away from each of the isolation openings, and an orthographic projection of the second extension portion of the third wrapping portion on the array substrate at least partially overlaps with an orthographic projection of the second extension portion of the fourth wrapping portion on the array substrate.

15. The display panel according to claim 13, wherein in a plurality of cross sections perpendicular to the extension direction of the isolation structure enclosing the third light-emitting sub-device, at least part of the second extension portion of the third wrapping portion has a third extension sub-length, and in a plurality of cross sections perpendicular to the extension direction of the isolation structure enclosing the second light-emitting sub-device, the second extension portion of the fourth wrapping portion has a fourth extension sub-length, the third extension sub-length being equal to the fourth extension sub-length.

16. The display panel according to claim 13, wherein the second extension portion of the third wrapping portion comprises a third extension section close to one side of the second light-emitting sub-device, the second extension portion of the fourth wrapping portion comprises a fourth extension section close to one side of the third light-emitting sub-device, and an orthographic projection of the third extension section on the array substrate at least partially overlaps at least partially overlaps with an orthographic projection of the fourth extension section on the array substrate; and
there is a second spacing between the third extension section and the fourth extension section in the direction perpendicular to the array substrate; and
part of the first extension portion located on the side of the third encapsulation unit close to the second light-emitting sub-device comprises a horizontal section and an inclined section connected to each other, an end of the inclined section away from the horizontal section being connected to the second extension portion.

17. The display panel according to claim 13, wherein in a plurality of cross sections perpendicular to the extension direction the first light-emitting sub-device, the length of the second extension portion of the first encapsulation unit is greater than or equal to 1.5 μm and less than or equal to 2 μm;
in the direction perpendicular to the plane where the array substrate is located and in the cross section of the isolation structure passing through the central axes of the first light-emitting sub-device and the second light-emitting sub-device which are adjacent to each other, the length of the horizontal section of the first extension portion located on the side of the third light-emitting sub-device close to the second light-emitting sub-device is equal to the length of the horizontal section of the first extension portion located on the side of the second light-emitting sub-device close to the third light-emitting sub-device;
the length of the horizontal section of the first extension portion located on the side of the third light-emitting sub-device close to the second light-emitting sub-device is greater than or equal to 1 μm and less than or equal to 1.2 μm; and
an included angle between the horizontal section and the inclined section of the first extension portion located on the side of the third light-emitting sub-device close to the second light-emitting sub-device is greater than or equal to 100° and less than or equal to 150°.

18. The display panel according to claim 17, wherein each of the light-emitting devices comprise a first electrode layer, a light-emitting functional layer and a second electrode layer which are sequentially stacked in a direction away from the array substrate;
there is a first spacing between the first extension section and the second extension section in the direction perpendicular to the array substrate;
the first spacing is equal to the sum of the thicknesses of the light-emitting functional layer and the second electrode layer of the second light-emitting sub-device.

19. The display panel according to claim 17, wherein a second spacing between the third extension section and the fourth extension section in the direction perpendicular to the array substrate and
wherein the second spacing is equal to the sum of the thicknesses of the light-emitting functional layer and the second electrode layer of the third light-emitting sub-device.

20. A display panel, comprising:
an array substrate;
an isolation structure located on one side of the array substrate, the isolation structure enclosing isolation openings;
light-emitting devices located in the isolation openings, the light-emitting devices comprising a plurality of light-emitting sub-devices; and
a first encapsulation layer located on a side of the light-emitting devices away from the array substrate, the first encapsulation layer comprising a plurality of encapsulation units correspondingly encapsulating the light-emitting devices, and at least part of each of the encapsulation units comprising a first encapsulation portion located in the isolation opening and a second encapsulation portion located on a side of the isolation structure away from the array substrate;
wherein the second encapsulation portions on different sides of the same light-emitting sub-device both have equal extension lengths in the direction away from the isolation opening.
